(19) United States
(12) Patent Application Publication
(10) Pub. No.: US 2019/0206905 A1
(43) Pub. Date: Jul. 4, 2019

(54) THIN FILM TRANSISTOR, MANUFACTURING METHOD THEREOF, ARRAY SUBSTRATE AND DISPLAY DEVICE

(71) Applicant: BOE Technology Group Co., Ltd., Beijing (CN)

(72) Inventor: Pengfei Gu, Beijing (CN)

(21) Appl. No.: 16/043,278

(22) Filed: Jul. 24, 2018

(30) Foreign Application Priority Data
Jan. 3, 2018 (CN) 201810004382.3

(51) Int. Cl. H01L 27/12; H01L 29/786; H01L 29/417; H01L 29/423; H01L 29/66

(52) U.S. Cl. CPC H01L 27/1225; H01L 29/7869; H01L 29/78669; H01L 29/66765; H01L 29/41733; H01L 29/42384; H01L 29/66757; H01L 29/78666

(57) ABSTRACT

A thin film transistor (TFT), manufacturing method thereof, array substrate and display device are provided. The TFT includes a carrier regulating layer, an insulating layer and an active layer. The insulating layer is located at a side of the active layer, the carrier regulating layer is located at a side of the insulating layer facing away from the active layer, orthographic projection of the active layer on the insulating layer covers orthographic projection of the carrier regulating layer on the insulating layer, and the carrier regulating layer is used to regulate carrier concentration in the active layer. By arranging the carrier regulating layer insulated from the active layer, carrier concentration in the carrier regulating layer may be regulated based on the need for different initial threshold voltages of the TFT. Thus, uniformity of the TFT film layers and accurate control of the initial threshold voltage of the TFT are achieved simultaneously.

The present application claims priority to Chinese Patent Application No. 201810004382.3, filed with the State Intellectual Property Office on Jan. 3, 2018 and titled “ARRAY SUBSTRATE, MANUFACTURING METHOD THEREOF AND DISPLAY DEVICE”, the entire contents of which are incorporated herein by reference.

### TECHNICAL FIELD

The present disclosure relates to, but is not limited to a thin film transistor, a manufacturing method thereof, an array substrate and a display device.

### BACKGROUND

With users' increasing demands for large-size display, large-size display products are receiving more and more attention. The thin film transistor (TFT) in an array substrate is a main electronic component of a display device, and its excellent electrical characteristics has been always one of the aims pursued by various display products.

### SUMMARY

The embodiments of the present disclosure provide a thin film transistor, a manufacturing method thereof, an array substrate and a display device.

The embodiments of the present disclosure provide a thin film transistor comprising: a carrier regulating layer, an insulating layer and an active layer, the insulating layer being located at a side of the active layer, the carrier regulating layer being located at a side of the insulating layer facing away from the active layer, an orthographic projection of the active layer on the insulating layer covering an orthographic projection of the carrier regulating layer on the insulating layer, wherein the carrier regulating layer is configured to regulate carrier concentration in the active layer.

Optionally, the carrier regulating layer is made of any one of P-type amorphous silicon and N-type amorphous silicon.

Optionally, the thin film transistor further comprises: a gate electrode, a gate insulating layer, and a source electrode and a drain electrode electrically connected to the active layer respectively, wherein the active layer is located between the insulating layer and the gate electrode, and the carrier regulating layer is located between a base substrate and the insulating layer.

Optionally, the orthographic projection of the active layer on the insulating layer completely overlaps the orthographic projection of the carrier regulating layer on the insulating layer.

Optionally, the thin film transistor further comprises: a gate electrode, a gate insulating layer, and a source electrode and a drain electrode electrically connected to the active layer respectively, wherein the gate electrode is located between a base substrate and the active layer, and the carrier regulating layer is located at a side of the insulating layer away from the base substrate.

Optionally, a thickness of the carrier regulating layer is 40-200 nm.

Optionally, a thickness of the active layer is 40-100 nm.

The embodiments of the present disclosure provide an array substrate, comprising: a base substrate, and a thin film transistor on the base substrate, wherein the thin film transistor comprises an active layer, an insulating layer located at a side of the active layer, and a carrier regulating layer located at a side of the insulating layer facing away from the active layer, an orthographic projection of the active layer on the base substrate covering an orthographic projection of the carrier regulating layer on the base substrate; wherein the carrier regulating layer is configured to regulate carrier concentration in the active layer

Optionally, in the array substrate provided in the embodiments of the present disclosure, the carrier regulating layer is made of any one of P-type amorphous silicon and N-type amorphous silicon.

Optionally, in the array substrate provided in the embodiments of the present disclosure, the thin film transistor further comprises: a gate electrode, a gate insulating layer, and a source electrode and a drain electrode electrically connected to the active layer respectively, the active layer being located between the insulating layer and the gate electrode, and the carrier regulating layer being located between the base substrate and the insulating layer.

Optionally, in the array substrate provided in the embodiments of the present disclosure, the orthographic projection of the active layer on the insulating layer completely overlaps the orthographic projection of the carrier regulating layer on the insulating layer.

Optionally, in the array substrate provided in the embodiments of the present disclosure, the thin film transistor further comprises: a gate electrode, a gate insulating layer, and a source electrode and a drain electrode electrically connected to the active layer respectively, the gate electrode being located between the base substrate and the active layer, and the carrier regulating layer being located at a side of the insulating layer away from the base substrate.

Optionally, a thickness of the carrier regulating layer is 40-200 nm.

Optionally, a thickness of the active layer is 40-100 nm.

Correspondingly, the embodiments of the present disclosure further provide a manufacturing method for a thin film transistor, comprising steps of: providing a base substrate; and forming a carrier regulating layer, an insulating layer and an active layer on the base substrate, the insulating layer being located at a side of the active layer, the carrier regulating layer being located at a side of the insulating layer facing away from the active layer, an orthographic projection of the active layer on the insulating layer covering an orthographic projection of the carrier regulating layer on the insulating layer, wherein the carrier regulating layer is configured to regulate carrier concentration in the active layer.

Optionally, a single patterning process and a single doping process are adopted to form the carrier regulating layer; wherein the carrier regulating layer is doped with positive ions when threshold voltage of the thin film transistor is greater than a specified value, and the carrier regulating layer is doped with negative ions when the threshold voltage of the thin film transistor is less than the specified value.

Optionally, in the above manufacturing method for a thin film transistor provided in the embodiments of the present disclosure, the thin film transistor further comprises: a gate electrode, a gate insulating layer, and a source electrode and a drain electrode electrically connected to the active layer respectively, the active layer being located between the insulating layer and the gate electrode, and the carrier regulating layer being located between the base substrate and the insulating layer, the manufacturing method comprising steps of: forming a pattern of the carrier regulating layer on the base substrate by a single patterning process and a single doping process; forming the insulating layer on the base substrate where the carrier regulating layer is formed; forming a pattern of the active layer on the base substrate where the insulating layer is formed; forming the gate insulating layer on the base substrate where the active layer is formed; forming a pattern of the gate electrode on the base substrate wherein the gate insulating layer is formed; and forming patterns of the source electrode and the drain electrode electrically connected to the active layer respectively on the base substrate where the gate electrode is formed.

Optionally, in the above manufacturing method for a thin film transistor provided in the embodiments of the present disclosure, the thin film transistor further comprises: a gate electrode, a gate insulating layer, and a source electrode and a drain electrode electrically connected to the active layer respectively, the gate electrode being located between the base substrate and the active layer, and the carrier regulating layer being located at a side of the insulating layer away from the base substrate, the manufacturing method comprising steps of: forming a pattern of the gate electrode on the base substrate; forming the gate insulating layer on the base substrate where the gate electrode is formed; forming a pattern of the active layer on the base substrate where the gate insulating layer is formed; forming the insulating layer on the base substrate where the active layer is formed; forming a pattern of the carrier regulating layer on the base substrate where the insulating layer is formed by a single patterning process and a single doping process; and forming patterns of the source electrode and the drain electrode electrically connected to the active layer respectively on the base substrate where the carrier regulating layer is formed.

Optionally, in the above manufacturing method for a thin film transistor provided in the embodiments of the present disclosure, the step of adopting a single patterning process and a single doping process to form the carrier regulating layer comprises: forming the carrier regulating layer made of P-type amorphous silicon or N-type amorphous silicon by a single patterning process and a single doping process.

Optionally, the step of adopting a single patterning process and a single doping process to form the carrier regulating layer comprises: depositing a carrier regulating layer film, performing a treatment on the carrier regulating layer film by a pattering process, and doping the thin film after the patterning process to obtain the carrier regulating layer.

Optionally, the step of adopting a single patterning process and a single doping process to form the carrier regulating layer comprises: depositing a carrier regulating layer film, doping the carrier regulating layer film, and performing a treatment on the doped carrier regulating layer film by a pattering process to obtain the carrier regulating layer.

Correspondingly, the embodiments of the present disclosure further provide a display apparatus, comprising the above array substrate provided in the embodiments of the present disclosure.

### BRIEF DESCRIPTION OF THE DRAWINGS

FIG. 1 is a diagram of a structure of a top-gate thin film transistor according to an embodiment of the present disclosure;

FIG. 2 is a diagram of a structure of a bottom-gate thin film transistor according to an embodiment of the present disclosure;

FIG. 3a to FIG. 3c show energy band diagrams before the carrier regulating layer and the active layer in the thin film transistor contact with the insulating layer, respectively and after the insulating layer is added according to an embodiment of the present disclosure.

FIG. 4 is a first flowchart of manufacturing method for a thin film transistor according to an embodiment of the present disclosure;

FIG. 5 is a second flowchart of manufacturing method for a thin film transistor according to an embodiment of the present disclosure;

FIG. 6a to FIG. 6f and FIG. 1 show cross-sectional diagrams after each step according to embodiment I of the present disclosure;

FIG. 7a to FIG. 7f and FIG. 2 show cross-sectional diagrams after each step according to embodiment II of the present disclosure;

FIG. 8 is a diagram of a structure of a top-gate array substrate according to an embodiment of the present disclosure;

FIG. 9 is a diagram of a structure of a bottom-gate array substrate according to an embodiment of the present disclosure; and

FIG. 10 is a diagram of a structure of a display apparatus according to an embodiment of the present disclosure.

### DETAILED DESCRIPTION

To make the principles and advantages of the present disclosure clearer, specific implementations of the thin film transistor, manufacturing method thereof and array substrate provided in the embodiments of the present disclosure are described in further detail with reference to the enclosed drawings.

Generally, the initial threshold voltage Vth of a TFT is controlled within a certain range based on different needs, while the initial threshold voltage Vth of a TFT is correlated with the carrier concentration in the active layer. The active layer of a FTF is usually made of metallic oxide. Herein, indium gallium zinc oxide is expected to become the material for the active layer in the array substrate in the next generation display technology for its advantages of high mobility, excellent uniformity and transparency, etc. When metallic oxide is adopted to make the active layer of the TFT, the carrier concentration may be controlled by controlling the total oxygen content in the gate insulating layer and the active layer so as to control the initial threshold voltage Vth of the TFT. When the total oxygen content in the gate insulating layer and the active layer is high, the acceptors increase, the electrons decrease and the Vth is positively biased. When the total oxygen content in the gate insulating layer and the active layer is low, the donors increase, the holes decrease and the Vth is negatively biased.

Additionally, there are requirements on the uniformity of the films when a TFT is manufactured. When the gate insulating layer and the active layer are made to be thin films with high oxygen content, the uniformity is good, while the Vth is positively biased and the Vth does not meet the requirement. When the gate insulating layer and the active layer are made to be thin films with moderate oxygen content, the Vth may meet the requirement, but the uniformity of the film layers is poor. In this case, the film layer is thick in the central area and thin in the edge area. Thus, when the above method of adjusting the oxygen content in the gate insulating layer and the active layer is adopted to regulate the Vth, it may lead to the following circumstances: the uniformity of the film layers is poor when the Vth meets the requirement, or the Vth cannot meet the requirement when the uniformity of the film layers is good.

In order to solve the above problem, the embodiments of the present disclosure provide a thin film transistor, manufacturing method thereof, array substrate, and display device. The thin film transistor and array substrate will be illustrated below with reference to the enclosed drawings. The thicknesses and shapes of the thin film layers in the enclosed drawings are intended to illustrate the present disclosure, and do not reflect the actual scales of the thin film transistor and array substrate.

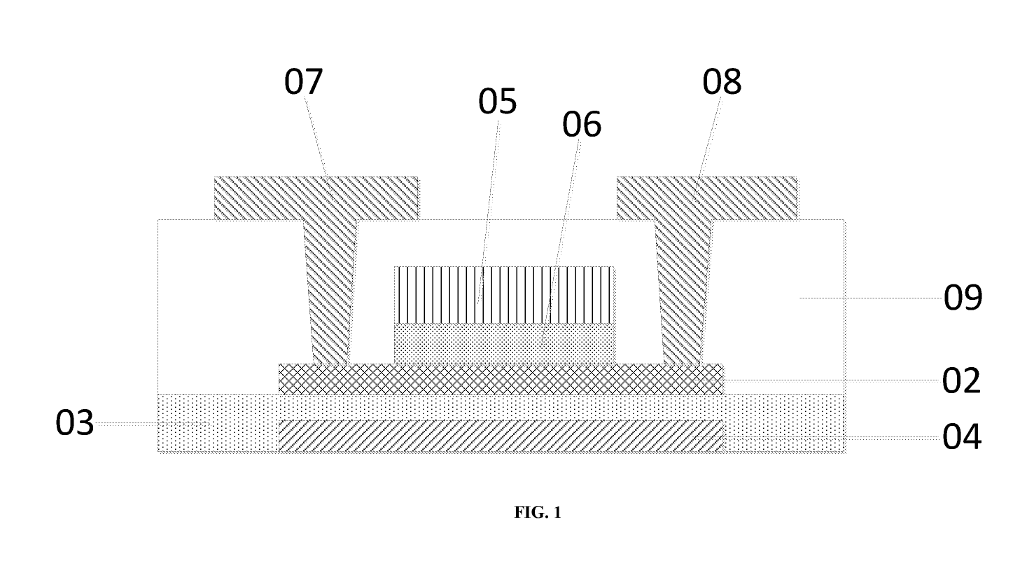

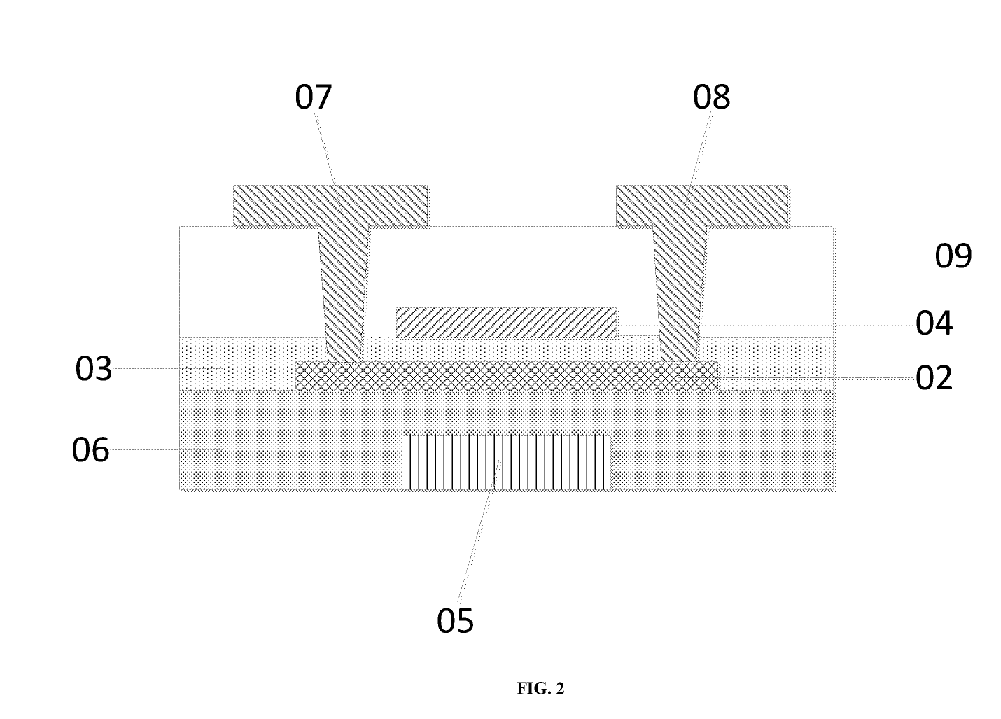

The embodiments of the present disclosure provide a thin film transistor. As shown in FIG. 1 and FIG. 2, the thin film transistor includes a carrier regulating layer 04, an insulating layer 03 and an active layer 02. The insulating layer 03 is located at a side of the active layer 02, and the carrier regulating layer 04 is located at a side of the insulating layer 03 facing away from the active layer 02. The orthographic projection of the active layer 02 on the insulating layer 03 covers the orthographic projection of the carrier regulating layer 04 on the insulating layer 03, wherein the carrier regulating layer 04 is configured to regulate the carrier concentration in the active layer 02.

In the thin film transistor provided in the embodiments of the present disclosure, an insulating layer and a carrier regulating layer are arranged at a side of the active layer. The orthographic projection of the active layer on the insulating layer covers the orthographic projection of the carrier regulating layer on the insulating layer, wherein the carrier regulating layer is configured to regulate the carrier concentration in the active layer. In the present disclosure, by arranging the carrier regulating layer insulated from the active layer through the insulating layer, the carrier concentration in the carrier regulating layer may be regulated based on the need for different initial threshold voltages Vth of the TFT. During the manufacturing process of the thin film transistor, the Fermi energy reaches to a balanced state once the active layer, the insulating layer and the carrier regulating layer contact. During the process that the Fermi energy reaches to the balanced state, the active layer induces the same amount of charges opposite to the charges in the carrier regulating layer to realize the balanced state of the Fermi energy. That is, the amount of charges produced in the active layer is the same as the amount of charges carried in the carrier regulating layer. Thus, the carrier concentration in the active layer may be controlled and regulated simply by regulating the carrier concentration in the carrier regulating layer in advance, thereby regulating the value of the initial threshold voltage Vth of the TFT. Therefore, according to the thin film transistor provided in the embodiments of the present disclosure, there is no need to adjust the total oxygen content in the gate insulating layer and the active layer to control the threshold voltage Vth of the TFT, and different initial threshold voltages Vth of the TFT may be controlled and regulated simply by regulating the carrier concentration in the carrier regulating layer. In this way, the uniformity of the TFT film layers and the accurate control of the initial threshold voltage Vth of the TFT may be achieved simultaneously, thereby improving the electrical characteristics of the TFT.

The above thin film transistor provided in the embodiments of the present disclosure may be a top-gate (the gate electrode 05 is above the active layer 02) thin film transistor as shown in FIG. 1, and may also be a bottom-gate (the gate electrode 05 is below the active layer 02) thin film transistor as shown in FIG. 2. Under both of these two circumstances, the carrier regulating layer and the gate electrode are located at two sides of the active layer.

In the embodiments of the present disclosure, the carrier concentration in the carrier regulating layer may be regulated through an ion-doping process. To take the active layer being made of indium gallium zinc oxide (IGZO) as an example, the initial threshold voltage Vth is supposed to approximate 0 when the IGZO contains 100 electrons. As there are requirements on the uniformity of the film layers, the gate insulating layer and the active layer adopt high oxygen film layers, which cause the amount of electrons to decrease. For example, the amount of electrons decreases to 50 from 100, and the Vth is positively biased under this circumstance. Thus, a method is needed to supplement 50 electrons such that the amount of electrons in the IGZO returns to 100. In the prior art, the initial threshold voltage Vth is enabled to meet the requirement by controlling the oxygen content. For example, the gate insulating layer and the active layer adopt low oxygen film layers. However, the uniformity of the low oxygen film layers is poor, thereby influencing the electrical characteristics of the TFT. In the embodiments of the present disclosure, the above problem is solved by arranging the carrier regulating layer insulated from the active layer through the insulating layer. As 50 electrons need to be supplemented into the IGZO to enable the initial threshold voltage Vth to approximate 0, in the embodiments of the present disclosure, an ion-doping process is adopted to dope the carrier regulating layer. Exemplarily, the carrier regulating layer is doped with nitrogen such that the holes in the carrier regulating layer approximate 50. During the manufacturing process of the thin film transistor, the Fermi energy reaches to a balanced state once the active layer, the insulating layer and the carrier regulating layer contact. Therefore, when voltage is applied to the thin film transistor, the active layer induces the same amount of charges, i.e., 50 electrons, opposite to the charges in the carrier regulating layer. That is, 50 electrons are supplemented into the active layer, thereby controlling and regulating the carrier concentration in the active layer. Thus, the amount of electrons in the IGZO returns to 100 such that the initial threshold voltage Vth approximates 0.

The principle of regulating the initial threshold voltage Vth of the above thin film transistor provided in the embodiments of the present disclosure will be elaborated with reference to the enclosed drawings.

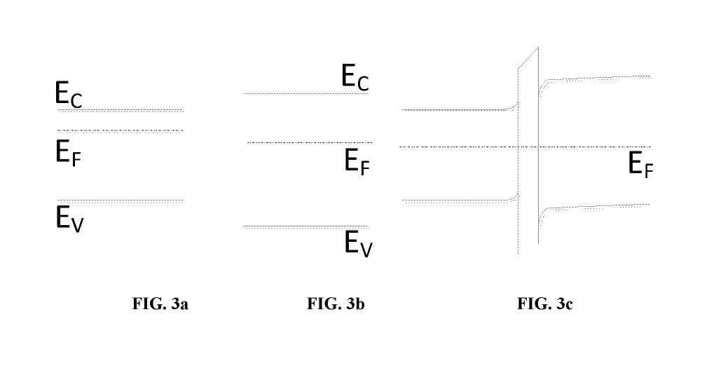

To take an example where the carrier regulating layer is made of amorphous silicon and the active layer is made of indium gallium zinc oxide, as shown in FIG. 3a to FIG. 3c, FIG. 3a and FIG. 3b show the energy band diagrams before the carrier regulating layer contacts with the insulating layer and the active layer contacts with the insulating layer, respectively. The respective conduction band EC, valence band EV and Fermi energy EF are shown in the drawings. The carrier regulating layer and the active layer have different Fermi energy EF. The EF position in the amorphous silicon may be changed by regulating the carrier concentration doped in the amorphous silicon. FIG. 3c shows the energy band diagram after an insulating layer is added between the carrier regulating layer and the active layer. Here, the Fermi energy EF on the left and right sides is consistent with each other. The carriers in the carrier regulating layer are injected into the active layer through charge induction, thereby realizing regulating the carrier concentration in the active layer by regulating the carrier concentration in the carrier regulating layer so as to further regulate and control the value of the initial threshold voltage of the TFT. Therefore, according to the thin film transistor provided in the embodiments of the present disclosure, the total oxygen content in the active layer and the gate insulating layer does not need to adjusted so as to control the threshold voltage Vth of the TFT, and different initial threshold voltages Vth of the TFT may be controlled and regulated simply by adjusting the carrier concentration in the carrier regulating layer to control the carrier concentration in the active layer. In this way, the uniformity of the TFT film layers and the accurate control of the initial threshold voltage Vth of the TFT may be achieved simultaneously, thereby improving the electrical characteristics of the TFT.

In the embodiments of the present disclosure, the thin film transistor having a specified initial threshold voltage may be manufactured first. Then, an electrical test may be performed to obtain the initial threshold voltage of the thin film transistor. When the initial threshold voltage is positively biased, a new thin film transistor needs to be manufactured again and the carrier regulating layer is doped when the thin film transistor is manufactured again such that the carrier regulating layer presents a P-type. When the initial threshold voltage is negatively biased, a new thin film transistor needs to be manufactured again and the carrier regulating layer is doped when the thin film transistor is manufactured again such that the carrier regulating layer presents an N-type. Afterwards, manufacture continues on the thin film transistor, and an electrical test is performed to gradually change the doping amount until the initial threshold voltage of the thin film transistor meets the requirement.

Exemplarily, in the above thin film transistor provided in the embodiments of the present disclosure, the carrier regulating layer is made of P-type amorphous silicon or N-type amorphous silicon as amorphous silicon may be doped with any ions to obtain the P-type amorphous silicon or N-type amorphous silicon. Therefore, the doping range is wide when amorphous silicon is taken as the base material of the carrier regulating layer, thereby achieving an efficient doping to obtain the P-type amorphous silicon or N-type amorphous silicon. Exemplarily, the amorphous silicon may be doped with the third main group elements, such as nitrogen, boron and the like to obtain the P-type amorphous silicon and the amorphous silicon may be doped with the fifth main group elements, such as phosphorus and the like to obtain the N-type amorphous silicon.

Certainly, the material for the carrier regulating layer provided in the present disclosure is not limited to amorphous silicon and the material for the carrier regulating layer may also be a semiconductor material containing In, Ga, Zn or Sn.

Exemplarily, in the above thin film transistor provided in the embodiments of the present disclosure, the thickness of the carrier regulating layer may be 40-200 nm. The effect of regulating the active layer cannot be achieved when the thickness of the carrier regulating layer is too small, and the thickness of the whole array substrate may be big when the thickness of the carrier regulating layer is too big, which is not beneficial for achieving a light and thin array substrate. In other embodiments, the thickness of the carrier regulating layer may other values, which is not limited here.

Exemplarily, in the above thin film transistor provided in the embodiments of the present disclosure, the thickness of the active layer may be 40-100 nm. In other embodiment, the thickness of the active layer may be other values, which is not limited here.

Exemplarily, in the above thin film transistor provided in the embodiments of the present disclosure, the insulating layer may be a SiOₓ layer (x is a positive number), such as a silicon dioxide layer.

When the thin film transistor described is a top-gate thin film transistor, as shown in FIG. 1, the thin film transistor further includes: a gate electrode 05, a gate insulating layer 06, and a source electrode 07 and a drain electrode 08 electrically connected to the active layer 02 respectively, wherein the active layer 02 is located between the insulating layer 03 and the gate electrode 05.

Furthermore, in the above thin film transistor provided in the embodiments of the present disclosure, as shown in FIG. 1, the orthographic projection of the active layer 02 on the insulating layer 03 completely overlaps the orthographic projection of the carrier regulating layer 04 on the insulating layer 03. That is, the area of the active layer 02 is the same as the area of the carrier regulating layer 04. This structure is convenient for designing and manufacturing the thin film transistor. During the actual manufacture, the area of the active layer 02 may also be different from the area of the carrier regulating layer 04, which is not limited in the present disclosure.

When the thin film transistor described is a bottom-gate thin film transistor, as shown in FIG. 2, the thin film transistor further includes: a gate electrode 05, a gate insulating layer 06, and a source electrode 07 and a drain electrode 08 electrically connected to the active layer 02 respectively, wherein the gate insulating layer 06 is located between the gate electrode 05 and the active layer 02, and the carrier regulating layer 04 is located at the side of the insulating layer 03 away from the gate electrode 05.

In the above thin film transistor provided in the embodiments of the present disclosure, the insulating material may be made of silicon dioxide.

Based on the same invention concept, the embodiments of the present disclosure further provide a manufacturing method for a thin film transistor, comprising steps of: providing a base substrate; and forming a carrier regulating layer, an insulating layer and an active layer on the base substrate, the insulating layer being located at a side of the active layer, the carrier regulating layer being located at a side of the insulating layer facing away from the active layer, the orthographic projection of the active layer on the insulating layer covering the orthographic projection of the carrier regulating layer on the insulating layer, and the carrier regulating layer is configured to regulate the carrier concentration in the active layer. Here, the step of forming the carrier regulating layer, the insulating layer and the active layer on the base substrate comprises: sequentially forming the carrier regulating layer, the insulating layer and the active layer, or sequentially forming the active layer, the insulating layer and the carrier regulating layer.

Herein, the step of forming the carrier regulating layer comprises: forming the carrier regulating layer by a single patterning process and a single doping process. The carrier regulating layer is doped with positive ions when the threshold voltage of the thin film transistor is greater than a specified value, and the carrier regulating layer is doped with negative ions when the threshold voltage of the thin film transistor is less than the specified value. The step of forming the carrier regulating layer by a single patterning process and a single doping process may be depositing a carrier regulating layer film first, performing a treatment on the pattern of the thin film by a pattering process, and doping the thin film after the patterning process to obtain the carrier regulating layer. Alternatively, the step of forming the carrier regulating layer by a single patterning process and a single doping process may be depositing a carrier regulating layer film first, doping the deposited thin film, and then performing a treatment on the pattern of the thin film by a pattering process to obtain the carrier regulating layer.

According to the manufacturing method for the thin film transistor provided in the embodiments of the present disclosure, by arranging the carrier regulating layer insulated from the active layer through the insulating layer, the carrier concentration in the carrier regulating layer may be regulated based on the need for different initial threshold voltages Vth of the TFT. During the manufacturing process of the thin film transistor, the Fermi energy reaches to a balanced state once the active layer, the insulating layer and the carrier regulating layer contact. During the process that the Fermi energy reaches to the balanced state, the active layer induces the same amount of charges opposite to the charges in the carrier regulating layer to realize the balanced state of the Fermi energy. That is, the amount of charges produced in the active layer is the same as the amount of charges carried in the carrier regulating layer. Thus, the carrier concentration in the active layer may be controlled and regulated simply by regulating the carrier concentration in the carrier regulating layer in advance, thereby regulating the value of the initial threshold voltage Vth of the TFT. Therefore, according to the manufacturing method for the thin film transistor provided in the embodiments of the present disclosure, there is no need to adjust the total oxygen content in the gate insulating layer and the active layer to control the threshold voltage Vth of the TFT, and different initial threshold voltages Vth of the TFT may be controlled and regulated simply by regulating the carrier concentration in the carrier regulating layer. In this way, the uniformity of the TFT film layers and the accurate control of the initial threshold voltage Vth of the TFT may be achieved simultaneously, thereby improving the electrical characteristics of the TFT.

In the embodiments of the present disclosure, when the threshold voltage of the thin film transistor is tested to be greater than the specified value, which may exemplarily be 0V, and the threshold voltage of the thin film transistor is tested to be 3V, that is, the threshold voltage is positively biased, and it indicates that there are few electrons in the active layer. Thus, we need supplement a corresponding amount of electrons into the active layer. Due to the existence of the carrier regulating layer, the active layer may induce the same amount of charges opposite to the charges in the carrier regulating layer. Since electrons need to be supplemented into the active layer, the carrier regulating layer is doped with positive ions. When the threshold voltage of the thin film transistor is tested to be smaller than the specified value, which may exemplarily be 0V and the threshold voltage of the thin film transistor is tested to be −3V, that is, the threshold voltage is negatively biased, and it indicates that there are few holes in the active layer. Thus, we need supplement a corresponding amount of holes into the active layer. Due to the existence of the carrier regulating layer, the active layer may induce the same amount of charges opposite to the charges in the carrier regulating layer. Since holes need to be supplemented into the active layer, the carrier regulating layer is doped with negative ions.

It should be noted that adopting a single patterning process and a single doping process refers to performing a doping process to the carrier regulating layer based on the need for carriers in the active layer during the patterning process to form the carrier regulating layer, to improve the manufacturing efficiency.

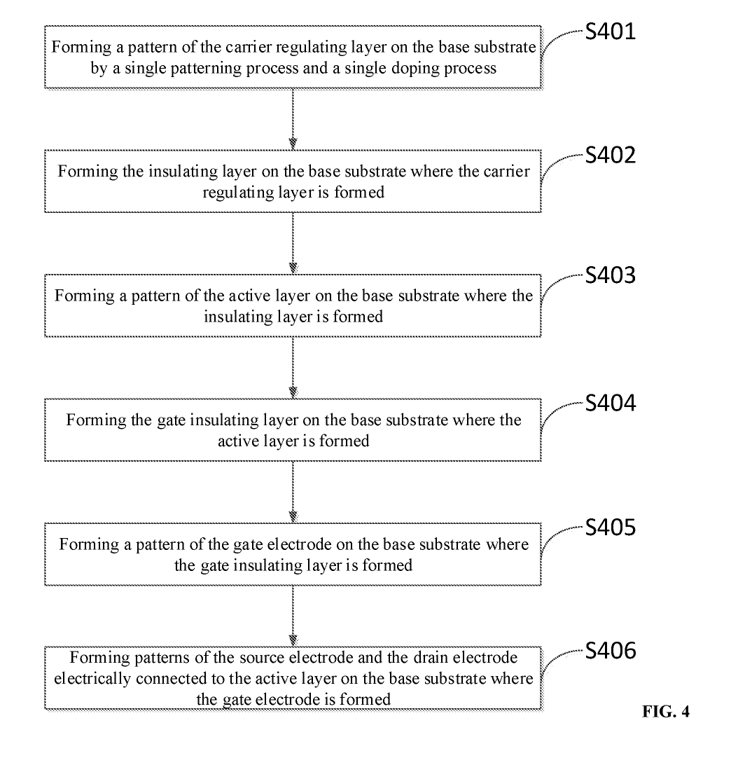

In the above manufacturing method provided in the embodiments of the present disclosure, the thin film layer may be a top-gate thin film transistor. The thin film transistor includes: a gate electrode, an active layer insulated from the gate electrode, and a source electrode and a drain electrode electrically connected to the active layer respectively. The active layer is located between the insulating layer and the gate electrode, and the carrier regulating layer is located between the base substrate and the insulating layer. As shown in FIG. 4, the manufacturing method includes the following steps.

In step S401, a pattern of the carrier regulating layer is formed on the base substrate by a single patterning process and a single doping process.

In step S402, the insulating layer is formed on the base substrate where the carrier regulating layer is formed.

In step S403, a pattern of the active layer is formed on the base substrate where the insulating layer is formed.

In step S404, the gate insulating layer is formed on the base substrate where the active layer is formed.

In step S405, a pattern of the gate electrode is formed on the base substrate where the gate insulating layer is formed.

In step S406, patterns of the source electrode and the drain electrode electrically connected to the active layer respectively are formed on the base substrate where the gate electrode is formed.

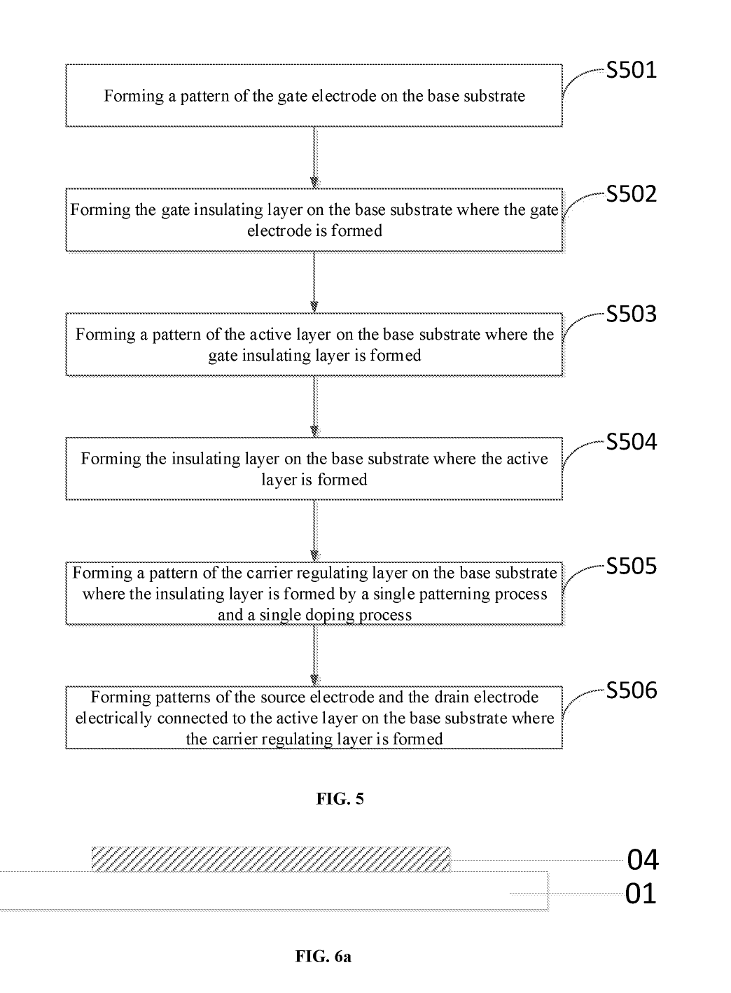

In the above manufacturing method provided in the embodiments of the present disclosure, the thin film transistor may be a bottom-gate thin film transistor. The thin film transistor includes: a gate electrode, an active layer insulated from the gate electrode, and a source electrode and a drain electrode electrically connected to the active layer respectively. The gate electrode is located between the base substrate and the active layer, and the carrier regulating layer is located at the side of the insulating layer away from the base substrate. As shown in FIG. 5, the manufacturing method includes the following step.

In step S501, a pattern of the gate electrode is formed on the base substrate.

In step S502, the gate insulating layer is formed on the base substrate where the gate electrode is formed.

In step S503, a pattern of the active layer is formed on the base substrate where the gate insulating layer is formed.

In step S504, the insulating layer is formed on the base substrate where the active layer is formed.

In step S505, a pattern of the carrier regulating layer is formed on the base substrate where the insulating layer is formed by a single patterning process and a single doping process.

In step S506, patterns of the source electrode and the drain electrode electrically connected to the active layer respectively are formed on the base substrate where the carrier regulating layer is formed.

In the above manufacturing method provided in the embodiments of the present disclosure, the step of forming the carrier regulating layer by a single patterning process and a single doping process includes: forming the carrier regulating layer made of P-type amorphous silicon or N-type amorphous silicon by a single patterning process and a single doping process. That is, a doping process is performed on the carrier regulating layer based on the need for carriers in the active layer during the patterning process to form the carrier regulating layer, to improve the manufacturing efficiency.

The structure of the thin film transistor in the present disclosure will be elaborated through two specific embodiments.

Embodiment I: the top-gate thin film transistor shown in FIG. 1 is taken as an example for illustration.

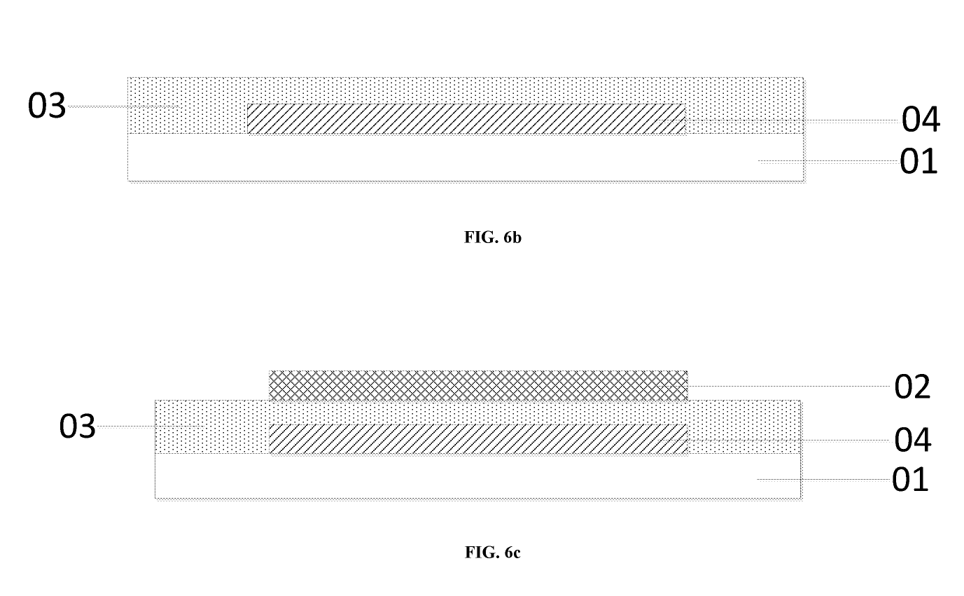

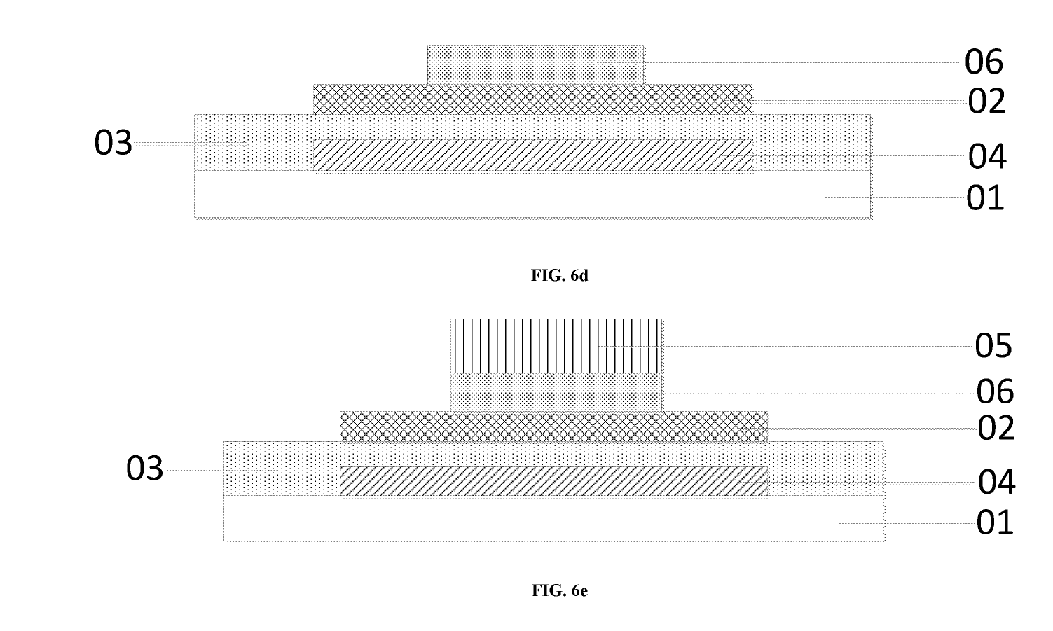

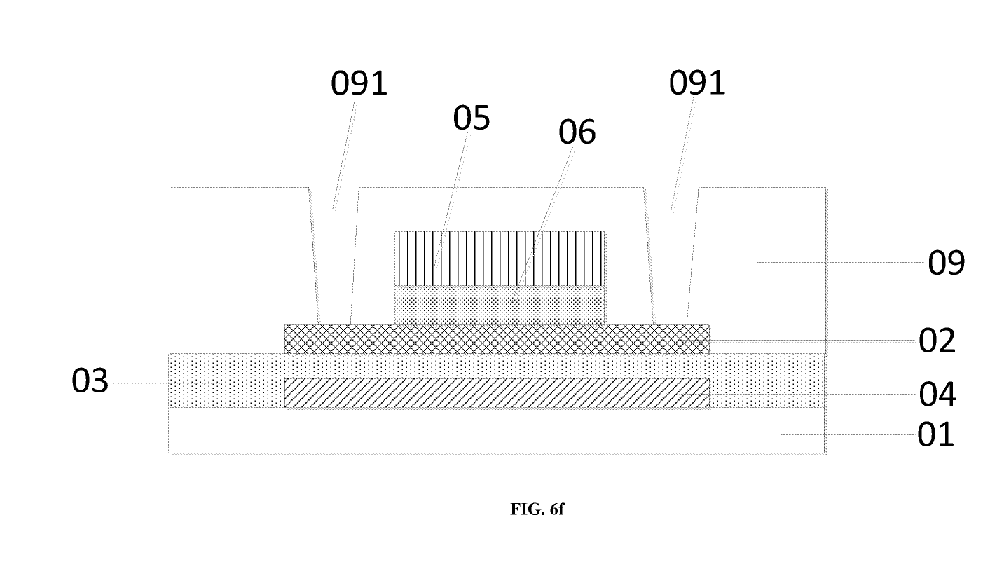

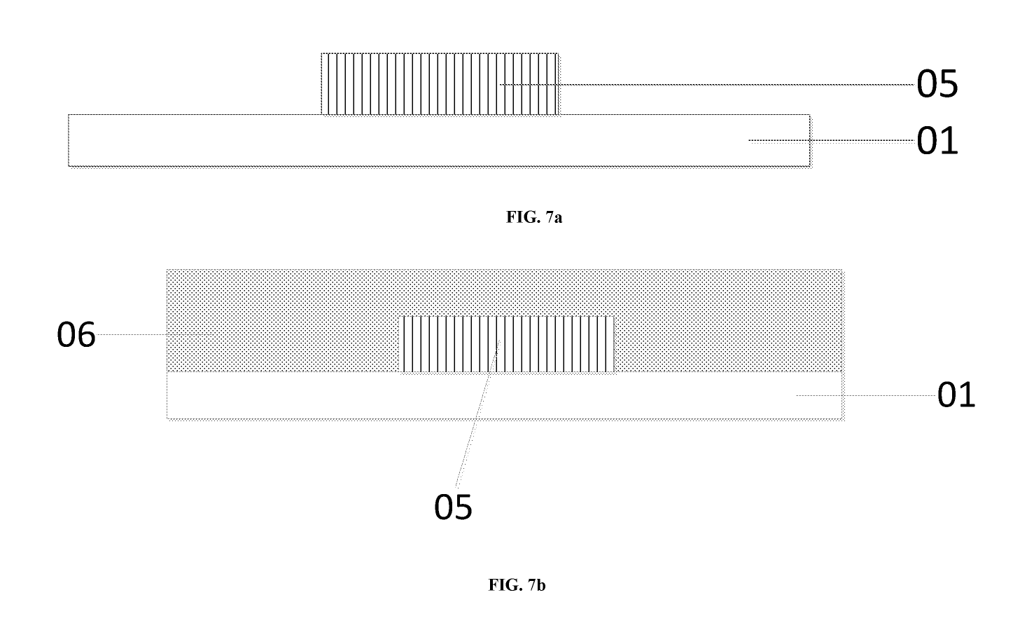

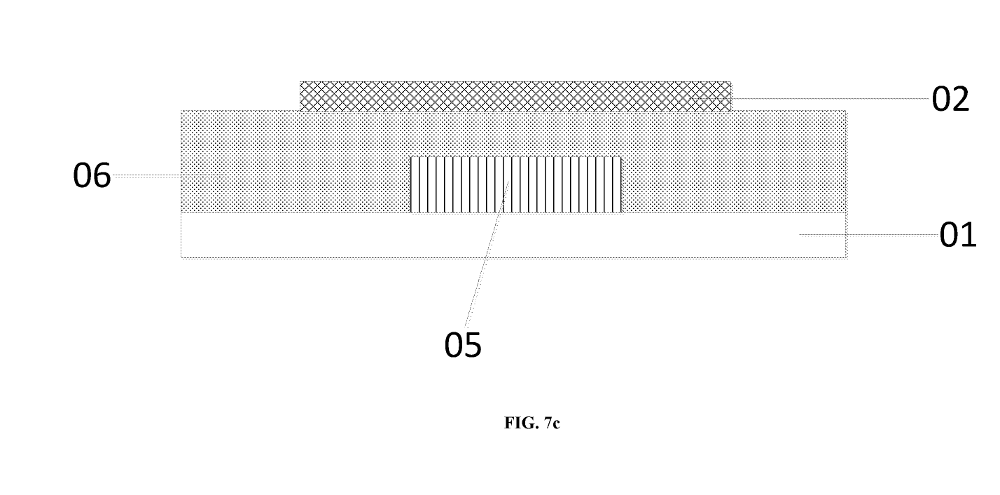

(1) As shown in FIG. 6a, a carrier regulating layer film with a thickness of 40-200 nm is deposited on the base substrate 01, and a single patterning process and a single doping process are performed on the carrier regulating layer film to form the pattern of the carrier regulating layer 04.

(2) As shown in FIG. 6b, the insulating layer 03 is deposited on the base substrate 01 where the carrier regulating layer 04 is formed. The insulating layer 03 covers the carrier regulating layer 04.

(3) As shown in FIG. 6c, an active layer film with a thickness of 40-100 nm is deposited on the base substrate 01 where the insulating layer 03 is formed, and a patterning process is performed on the active layer film to obtain the pattern of the active layer 02.

(4) As shown in FIG. 6d, a pattern of the gate insulating layer 06 is formed on the base substrate 01 where the active layer 02 is formed.

(5) As shown in FIG. 6e, a pattern of the gate electrode 05 is formed on the base substrate 01 where the gate insulating layer 06 is formed.

(6) As shown in FIG. 6f, an interlayer medium layer 09 is deposited on the base substrate 01 where the gate electrode 05 is formed, and a via hole 091 passing through the interlayer medium layer 09 is formed through a single patterning process.

(7) As shown in FIG. 1, patterns of the source electrode 07 and the drain electrode 08 electrically connected to the active layer 02 are formed on the base substrate 01 where the interlayer medium layer 09 is formed through the vie hole 091.

The top-gate thin film transistor shown in FIG. 1 provided in the present disclosure may be obtained through steps (1) to (7) in embodiment I.

Embodiment II: the bottom-gate thin film transistor shown in FIG. 2 is taken as an example for illustration.

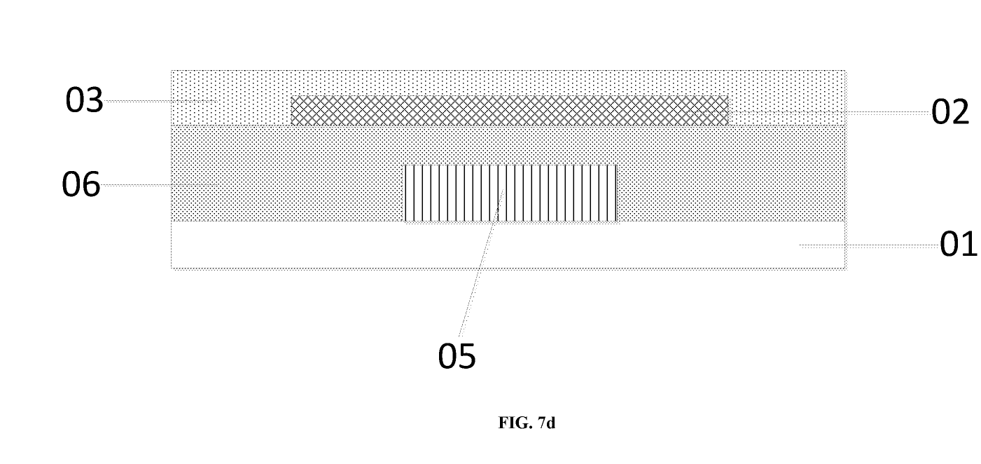

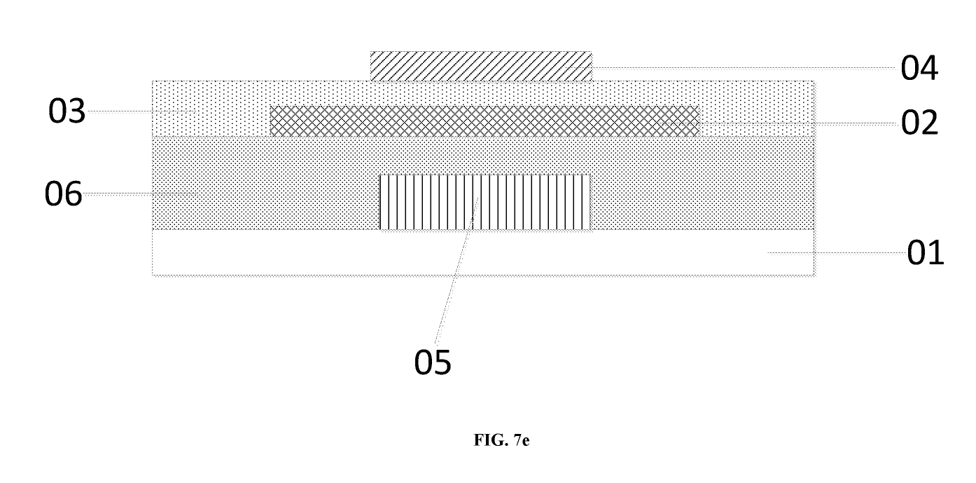

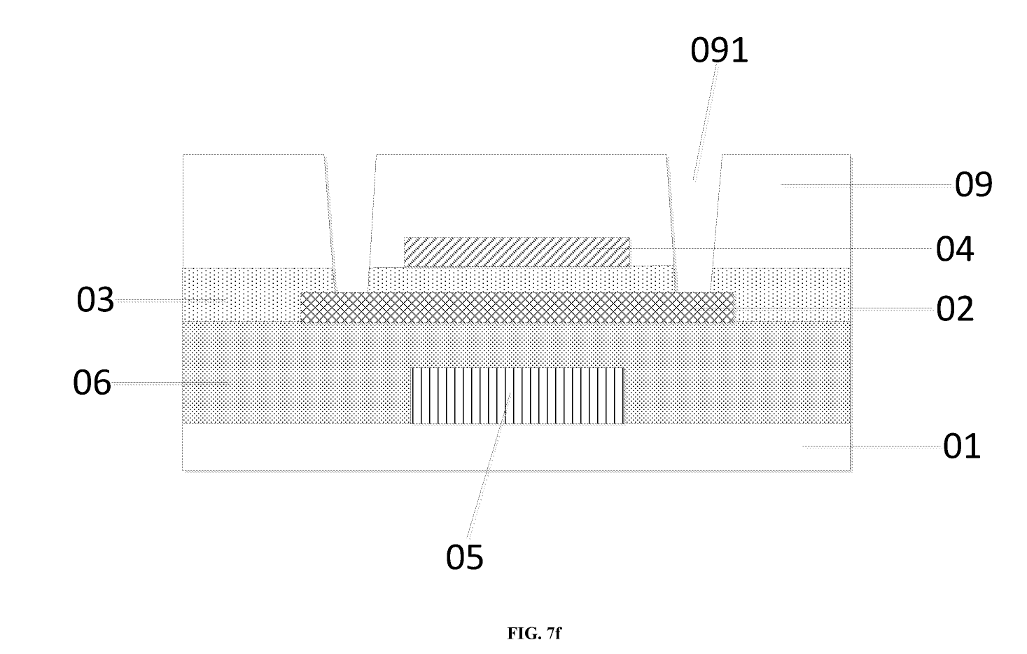

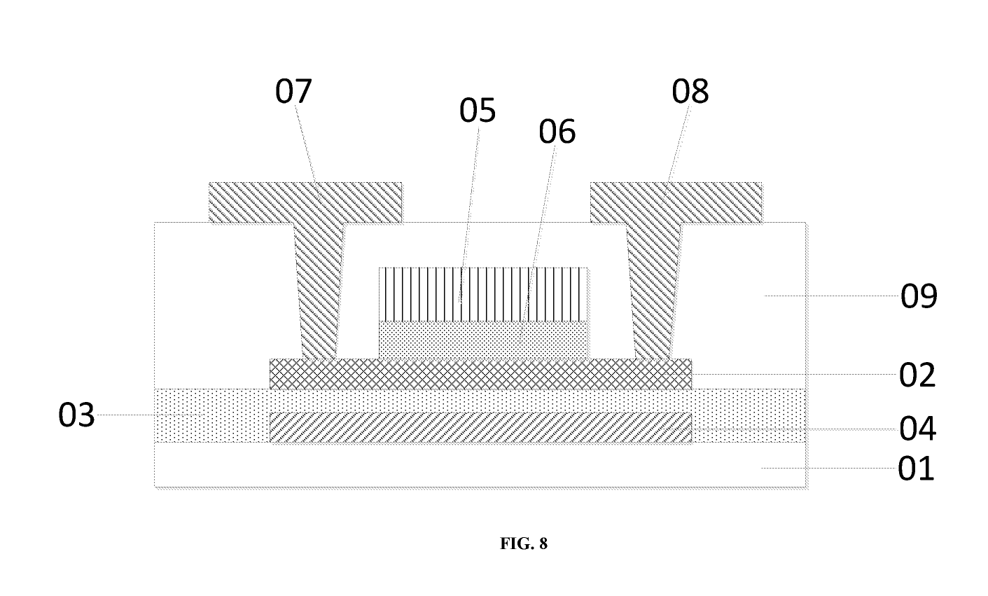

(1′) As shown in FIG. 7a, a pattern of the gate electrode 05 is formed on the base substrate 01.

(2′) As shown in FIG. 7b, a pattern of the gate insulating layer 06 is formed on the base substrate 01 where the gate electrode 05 is formed.

(3′) As shown in FIG. 7c, an active layer film with a thickness of 40-100 nm is deposited on the base substrate 01 where the gate insulating layer 06 is formed, and a patterning process is performed on the active layer film to obtain the pattern of the active layer 02.

(4′) As shown in FIG. 7d, the insulating layer 03 is deposited on the base substrate 01 where the active layer 02 is formed.

(5′) As shown in FIG. 7e, a carrier regulating layer film with a thickness of 40-200 nm is deposited on the base substrate 01 where the insulating layer 03 is formed, and a single patterning and a single doping process are performed on the carrier regulating layer film to form the pattern of the carrier regulating layer 04.

(6′) As shown in FIG. 7f, an interlayer medium layer 09 is deposited on the base substrate 01 where the carrier regulating layer 04 is formed, and a via hole 091 passing through the interlayer medium layer 09 is formed through a single patterning process.

(7′) As shown in FIG. 2, patterns of the source electrode 07 and the drain electrode 08 electrically connected to the active layer 02 are formed on the base substrate 01 where the interlayer medium layer 09 is formed through the vie hole 091.

The bottom-gate thin film transistor shown in FIG. 2 provided in the present disclosure may be obtained through steps (1′) to (7′) in embodiment II.

It should be noted that during the above manufacturing process of the thin film transistor provided in the embodiments of the present disclosure, the pattering process may include a photoetching process, or may include a photoetching process and etching steps. Meanwhile, the pattering process may also include processes, such printing, ink-jetting and the like, for forming the specified pattern. The photoetching process refer to the process including the procedures of film formation, exposure, developing and the like for forming a pattern using photoresist, mask plates, exposure machines, etc. During implementation, the corresponding patterning process may be selected based on the structure to be formed in the present disclosure.

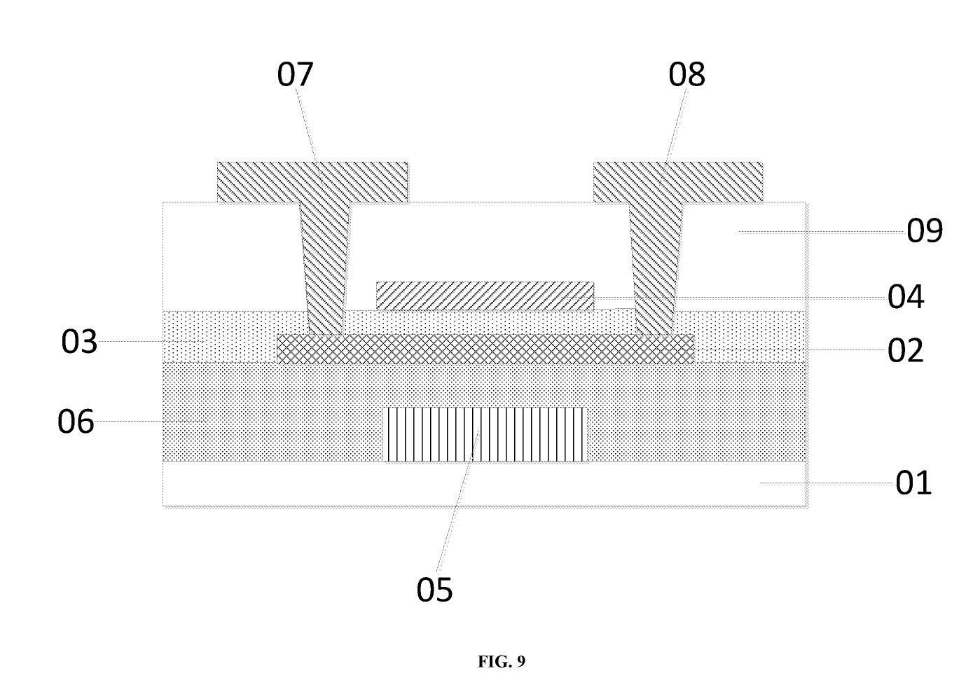

The embodiments of the present disclosure provide an array substrate, including the thin film transistor provided in the above embodiments. Further, as shown in FIG. 8 and FIG. 9, the array substrate includes: a base substrate 01, and a thin film transistor on the base substrate 01. The thin film transistor includes an active layer 02, an insulating layer 03 located at a side of the active layer 02, and a carrier regulating layer 04 located at a side of the insulating layer 03 facing away from the active layer 02. The orthographic projection of the active layer 02 on the base substrate 01 covers the orthographic projection of the carrier regulating layer 04 on the base substrate 01. Wherein, the carrier regulating layer 04 is configured to regulate the carrier concentration in the active layer 02. Generally, a plurality of thin film transistors in a matrix is arranged on the base substrate, and only one of the thin film transistors is taken as an example for illustration in the drawings.

The array substrate provided in the embodiments of the present disclosure includes: a base substrate, and thin film transistors on the base substrate. The thin film transistor includes an active layer, an insulating layer located at a side of the active layer, and a carrier regulating layer located at a side of the insulating layer facing away from the active layer. The orthographic projection of the active layer on the base substrate covers the orthographic projection of the carrier regulating layer on the base substrate. Wherein, the carrier regulating layer is configured to regulate the carrier concentration in the active layer. In the embodiments of the present disclosure, by arranging the carrier regulating layer insulated from the active layer through the insulating layer, the carrier concentration in the carrier regulating layer may be regulated based on the need for different initial threshold voltages Vth of the TFT. During the manufacturing process of the thin film transistor, the Fermi energy reaches to a balanced state once the active layer, the insulating layer and the carrier regulating layer contact. During the process that the Fermi energy reaches to the balanced state, the active layer induces the same amount of charges opposite to the charges in the carrier regulating layer to realize the balanced state of the Fermi energy. That is, the amount of charges produced in the active layer is the same as the amount of charges carried in the carrier regulating layer. Thus, the carrier concentration in the active layer may be controlled and regulated simply by regulating the carrier concentration in the carrier regulating layer in advance, thereby regulating the value of the initial threshold voltage Vth of the TFT. Therefore, according to the array substrate provided in the embodiments of the present disclosure, there is no need to adjust the total oxygen content in the gate insulating layer and the active layer to control the threshold voltage Vth of the TFT, and different initial threshold voltages Vth of the TFT may be controlled and regulated simply by regulating the carrier concentration in the carrier regulating layer. In this way, the uniformity of the TFT film layers and the accurate control of the initial threshold voltage Vth of the TFT may be achieved simultaneously, thereby improving the electrical characteristics of the TFT.

The above array substrate provided in the embodiments of the present disclosure may be a top-gate (the gate electrode 05 is above the active layer 02) array substrate as shown in FIG. 8, and may also be a bottom-gate (the gate electrode 05 is below the active layer 02) array substrate as shown in FIG. 9.

In the embodiments of the present disclosure, the carrier concentration in the carrier regulating layer may be regulated through an ion-doping process. To take the active layer being made of indium gallium zinc oxide (IGZO) as an example, the initial threshold voltage Vth is supposed to approximate 0 when the IGZO contains 100 electrons. As there are requirements on the uniformity of the film layers, the gate insulating layer and the active layer adopt high oxygen film layers, which cause the amount of electrons to decrease. For example, the amount of electrons decreases to 50 from 100, and the Vth is positively biased under this circumstance. Thus, a method is needed to supplement 50 electrons such that the amount of electrons in the IGZO returns to 100. In the prior art, the initial threshold voltage Vth is enabled to meet the requirement by controlling the oxygen content. For example, the gate insulating layer and the active layer adopt low oxygen film layers. However, the uniformity of the low oxygen film layers is poor, thereby influencing the electrical characteristics of the TFT. In the embodiments of the present disclosure, the carrier regulating layer insulated from the active layer through the insulating layer is provided. As 50 electrons need to be supplemented into the IGZO to enable the initial threshold voltage Vth to approximate 0, in the present disclosure, an ion-doping process is adopted to dope the carrier regulating layer. Exemplarily, the carrier regulating layer is doped with nitrogen such that the holes in the carrier regulating layer approximate 50. During the manufacturing process of the thin film transistor, the Fermi energy reaches to a balanced state once the active layer, the insulating layer and the carrier regulating layer contact. Therefore, when voltage is applied to the thin film transistor, the active layer induces the same amount of charges, i.e., 50 electrons, opposite to the charges in the carrier regulating layer. That is, 50 electrons are supplemented into the active layer, thereby controlling and regulating the carrier concentration in the active layer. Thus, the amount of electrons in the IGZO returns to 100 such that the initial threshold voltage Vth approximates 0.

The principle of regulating the initial threshold voltage Vth of the above array substrate provided in the embodiments of the present disclosure will be elaborated with reference to the enclosed drawings.

To take an example where the carrier regulating layer is made of amorphous silicon and the active layer is made of indium gallium zinc oxide, as shown in FIG. 3a to FIG. 3c, FIG. 3a and FIG. 3b shows the energy band diagrams before the carrier regulating layer contacts with the insulating layer and the active layer contacts with the insulating layer, respectively. The respective conduction band EC, valence band EV and Fermi energy EF are shown in the drawings. The carrier regulating layer and the active layer have different Fermi energy EF. The EF position in the amorphous silicon may be changed by regulating the carrier concentration doped in the amorphous silicon. FIG. 3c shows the energy band diagram after an insulating layer is added between the carrier regulating layer and the active layer. Here, the Fermi energy EF on the left and right sides is consistent with each other. The carriers in the carrier regulating layer are injected into the active layer through charge induction, thereby realizing regulating the carrier concentration in the active layer by regulating the carrier concentration in the carrier regulating layer so as to further regulate and control the value of the initial threshold voltage of the TFT. Therefore, according to the array substrate provided in the embodiments of the present disclosure, the total oxygen content in the active layer and the gate insulating layer does not need to adjusted so as to control the threshold voltage Vth of the TFT, and different initial threshold voltages Vth of the TFT may be controlled and regulated simply by adjusting the carrier concentration in the carrier regulating layer to control the carrier concentration in the active layer. In this way, the uniformity of the TFT film layers and the accurate control of the initial threshold voltage Vth of the TFT may be achieved simultaneously, thereby improving the electrical characteristics of the TFT.

In the embodiments of the present disclosure, the thin film transistor having a specified initial threshold voltage may be manufactured first. Then, an electrical test may be performed to obtain the initial threshold voltage of the thin film transistor. When the initial threshold voltage is positively biased, a new thin film transistor needs to be manufactured again and the carrier regulating layer is doped when the thin film transistor is manufactured again such that the carrier regulating layer presents a P-type. When the initial threshold voltage is negatively biased, a new thin film transistor needs to be manufactured again and the carrier regulating layer is doped when the thin film transistor is manufactured again such that the carrier regulating layer presents an N-type. Afterwards, manufacture continues on the thin film transistor, and an electrical test is performed until the initial threshold voltage of the thin film transistor meets the requirement. During implementation, if the initial threshold voltage obtained during the electrical test does not meet the requirement, the doping amount may be gradually changed through tests until the initial threshold voltage of the thin film transistor meets the requirement.

Exemplarily, in the above array substrate provided in the embodiments of the present disclosure, the carrier regulating layer is made of P-type amorphous silicon or N-type amorphous silicon as amorphous silicon may be doped with any ions to obtain the P-type amorphous silicon or N-type amorphous silicon. Therefore, the doping range is wide when amorphous silicon is taken as the base material of the carrier regulating layer, thereby achieving an efficient doping to obtain the P-type amorphous silicon or N-type amorphous silicon. Exemplarily, the amorphous silicon may be doped with the third main group elements, such as nitrogen, boron and the like to obtain the P-type amorphous silicon and the amorphous silicon may be doped with the fifth main group elements, such as phosphorus and the like to obtain the N-type amorphous silicon.

Certainly, the material for the carrier regulating layer provided in the present disclosure is not limited to amorphous silicon and the material for the carrier regulating layer may also be a semiconductor material containing In, Ga, Zn or Sn.

Exemplarily, in the above array substrate provided in the embodiments of the present disclosure, the thickness of the carrier regulating layer may be 40-200 nm. The effect of regulating the active layer cannot be achieved when the thickness of the carrier regulating layer is too small, and the thickness of the whole array substrate may be big when the thickness of the carrier regulating layer is too big, which is unfavourable for achieving a light and thin array substrate. In other embodiments, the thickness of the carrier regulating layer may other values, which is not limited here.

Exemplarily, in the above array substrate provided in the embodiments of the present disclosure, the thickness of the active layer may be 40-100 nm. In other embodiment, the thickness of the active layer may be other values, which is not limited here.

Exemplarily, in the above array substrate provided in the embodiments of the present disclosure, the insulating layer may be a SiOₓ layer (x is a positive number), such as a silicon dioxide layer.

When the array substrate provided in the embodiments of the present disclosure is a top-gate array substrate, as shown in FIG. 8, the thin film transistor further includes: a gate electrode 05, a gate insulating layer 06, and a source electrode 07 and a drain electrode 08 electrically connected to the active layer 03. The active layer 02 is located between the insulating layer 03 and the gate electrode 05, and the carrier regulating layer 04 is located between the base substrate 01 and the insulating layer 03.

Furthermore, in the array substrate provided in the embodiments of the present disclosure, as shown in FIG. 8, the orthographic projection of the active layer 02 on the base substrate 01 completely overlaps the orthographic projection of the carrier regulating layer 04 on the base substrate. That is, the area of the active layer 02 is the same as the area of the carrier regulating layer 04. This structure is convenient for designing and manufacturing the thin film transistor. During the manufacture, the area of the active layer 02 may also be different from the area of the carrier regulating layer 04, which is not limited in the present disclosure.

When the array substrate provided in the embodiments of the present disclosure is a bottom-gate array substrate, as shown in FIG. 9, the thin film transistor further includes: a gate electrode 05, a gate insulating layer 06, and a source electrode 07 and a drain electrode 08 electrically connected to the active layer 02 respectively. The gate electrode 05 is located between the base substrate 01 and the active layer 02, and the carrier regulating layer 04 is located at the side of the insulating layer 03 away from the base substrate 01.

In the array substrate provided in the embodiments of the present disclosure, the insulating material may be made of silicon dioxide.

Based on the same invention concept, the embodiments of the present disclosure further provide a manufacturing method for an array substrate, including: providing a base substrate; and forming thin film transistors on the base substrate. The thin film transistor includes: an active layer, an insulating layer located at a side of the active layer, and a carrier regulating layer located at a side of the insulating layer facing away from the active layer. The orthographic projection of the active layer on the base substrate covers the orthographic projection of the carrier regulating layer on the base substrate.

Herein, the carrier regulating layer may be made in the following way: adopting a single patterning process and a single doping process to form the carrier regulating layer. The carrier regulating layer is doped with positive ions when the threshold voltage of the thin film transistor is greater than a specified value, and the carrier regulating layer is doped with negative ions when the threshold voltage of the thin film transistor is less than the specified value. Herein, the step of adopting a single patterning process and a single doping process to form the carrier regulating layer refers to depositing a carrier regulating layer film first, performing a treatment on the pattern of the thin film by a pattering process, and doping the thin film after the patterning process to obtain the carrier regulating layer. Alternatively, the step of adopting a single patterning process and a single doping process to form the carrier regulating layer refers to depositing a carrier regulating layer film first, doping the deposited thin film, and then performing a treatment on the pattern of the thin film by a pattering process to obtain the carrier regulating layer.

According to the manufacturing method for the array substrate provided in the embodiments of the present disclosure, by arranging the carrier regulating layer insulated from the active layer through the insulating layer, the carrier concentration in the carrier regulating layer may be regulated based on the need for different initial threshold voltages Vth of the TFT. During the manufacturing process of the thin film transistor, the Fermi energy reaches to a balanced state once the active layer, the insulating layer and the carrier regulating layer contact. During the process that the Fermi energy reaches to the balanced state, the active layer induces the same amount of charges opposite to the charges in the carrier regulating layer to realize the balanced state of the Fermi energy. That is, the amount of charges produced in the active layer is the same as the amount of charges carried in the carrier regulating layer. Thus, the carrier concentration in the active layer may be controlled and regulated simply by regulating the carrier concentration in the carrier regulating layer in advance, thereby regulating the value of the initial threshold voltage Vth of the TFT. Therefore, according to the manufacturing method for the array substrate provided in the embodiments of the present disclosure, there is no need to adjust the total oxygen content in the gate insulating layer and the active layer to control the threshold voltage Vth of the TFT, and different initial threshold voltages Vth of the TFT may be controlled and regulated simply by regulating the carrier concentration in the carrier regulating layer. In this way, the uniformity of the TFT film layers and the accurate control of the initial threshold voltage Vth of the TFT may be achieved simultaneously, thereby improving the electrical characteristics of the TFT.

In the embodiments of the present disclosure, when the threshold voltage of the thin film transistor is tested to be greater than the specified value, which may exemplarily be 0V and the threshold voltage of the thin film transistor is tested to be 3V, that is, the threshold voltage is positively biased, and it indicates that there are few electrons in the active layer. Thus, we need supplement a corresponding amount of electrons into the active layer. Due to the existence of the carrier regulating layer, the active layer may induce the same amount of charges opposite to the charges in the carrier regulating layer. Since electrons need to be supplemented into the active layer, the carrier regulating layer is doped with positive ions. When the threshold voltage of the thin film transistor is tested to be smaller than the specified value, which may exemplarily be 0V and the threshold voltage of the thin film transistor is tested to be −3V, that is, the threshold voltage is negatively biased, and it indicates that there are few holes in the active layer. Thus, we need supplement a corresponding amount of holes into the active layer. Due to the existence of the carrier regulating layer, the active layer may induce the same amount of charges opposite to the charges in the carrier regulating layer. Since holes need to be supplemented into the active layer, the carrier regulating layer is doped with negative ions.

It should be noted that adopting a single patterning process and a single doping process refers to performing a doping process to the carrier regulating layer based on the need for carriers in the active layer during the patterning process to form the carrier regulating layer, to improve the manufacturing efficiency.

In the above manufacturing method provided in the embodiments of the present disclosure, the thin film transistor may be a top-gate thin film transistor. The thin film transistor includes: a gate electrode, an active layer insulated from the gate electrode, and a source electrode and a drain electrode electrically connected to the active layer respectively. The active layer is located between the insulating layer and the gate electrode, and the carrier regulating layer is located between the base substrate and the insulating layer. As shown in FIG. 4, the manufacturing method for the array substrate includes the following steps.

In step S401, a pattern of the carrier regulating layer is formed on the base substrate by a single patterning process and a single doping process.

In step S402, the insulating layer is formed on the base substrate where the carrier regulating layer is formed.

In step S403, a pattern of the active layer is formed on the base substrate where the insulating layer is formed.

In step S404, the gate insulating layer is formed on the base substrate where the active layer is formed.

In step S405, a pattern of the gate electrode is formed on the base substrate where the gate insulating layer is formed.

In step S406, patterns of the source electrode and the drain electrode electrically connected to the active layer respectively are formed on the base substrate where the gate electrode is formed.

In the above manufacturing method provided in the embodiments of the present disclosure, the thin film transistor may be a bottom-gate thin film transistor. The thin film transistor includes: a gate electrode, an active layer insulated from the gate electrode, and a source electrode and a drain electrode electrically connected to the active layer respectively. The gate electrode is located between the base substrate and the active layer, and the carrier regulating layer is located at the side of the insulating layer away from the base substrate. As shown in FIG. 5, the manufacturing method includes the following step.

In step S501, a pattern of the gate electrode is formed on the base substrate.

In step S502, the gate insulating layer is formed on the base substrate where the gate electrode is formed.

In step S503, a pattern of the active layer is formed on the base substrate where the gate insulating layer is formed.

In step S504, the insulating layer is formed on the base substrate where the active layer is formed.

In step S505, a pattern of the carrier regulating layer is formed on the base substrate where the insulating layer is formed by a single patterning process and a single doping process.

In step S506, patterns of the source electrode and the drain electrode electrically connected to the active layer respectively are formed on the base substrate where the carrier regulating layer is formed.

In the above manufacturing method provided in the embodiments of the present disclosure, the step of forming the carrier regulating layer by a single patterning process and a single doping process includes: forming the carrier regulating layer made of P-type amorphous silicon or N-type amorphous silicon by a single patterning process and a single doping process. That is, a doping process is performed on the carrier regulating layer based on the need for carriers in the active layer during the patterning process to form the carrier regulating layer, to improve the manufacturing efficiency.

The structure of the array substrate in the present disclosure will be elaborated through two specific embodiments.

Embodiment I: the top-gate array substrate shown in FIG. 8 is taken as an example for illustration.

(1) As shown in FIG. 6a, a carrier regulating layer film with a thickness of 40-200 nm is deposited on the base substrate 01, and a single patterning process and a single doping process are performed on the carrier regulating layer film to form the pattern of the carrier regulating layer 04.

(2) As shown in FIG. 6b, the insulating layer 03 is deposited on the base substrate 01 where the carrier regulating layer 04 is formed. The insulating layer 03 covers the carrier regulating layer 04.

(3) As shown in FIG. 6c, an active layer film with a thickness of 40-100 nm is deposited on the base substrate 01 where the insulating layer 03 is formed, and a patterning process is performed on the active layer film to obtain the pattern of the active layer 02.

(4) As shown in FIG. 6d, the pattern of the gate insulating layer 06 is formed on the base substrate 01 where the active layer 02 is formed.

(5) As shown in FIG. 6e, the pattern of the gate electrode 05 is formed on the base substrate 01 where the gate insulating layer 06 is formed.

(6) As shown in FIG. 6f, an interlayer medium layer 09 is deposited on the base substrate 01 where the gate electrode 05 is formed, and a via hole 091 passing through the interlayer medium layer 09 is formed through a single patterning process.

(7) As shown in FIG. 8, the patterns of the source electrode 07 and the drain electrode 08 electrically connected to the active layer 02 are formed on the base substrate 01 where the interlayer medium layer 09 is formed through the vie hole 091.

The top-gate array substrate shown in FIG. 8 provided in the present disclosure may be obtained through steps (1) to (7) in embodiment I.

Embodiment II: the bottom-gate array substrate shown in FIG. 9 is taken as an example for illustration.

(1′) As shown in FIG. 7a, the pattern of the gate electrode 05 is formed on the base substrate 01.

(2′) As shown in FIG. 7b, the pattern of the gate insulating layer 06 is formed on the base substrate 01 where the gate electrode 05 is formed.

(3′) As shown in FIG. 7c, an active layer film with a thickness of 40-100 nm is formed on the base substrate 01 where the gate insulating layer 06 is formed, and a patterning process is performed on the active layer film to obtain the pattern of the active layer 02.

(4′) As shown in FIG. 7d, the insulating layer 03 is deposited on the base substrate 01 where the active layer 02 is formed.

(5′) As shown in FIG. 7e, the carrier regulating layer film with a thickness of 40-200 nm is deposited on the base substrate 01 where the insulating layer 03 is formed, and a single patterning and a single doping process are performed on the carrier regulating layer film to form the pattern of the carrier regulating layer 04.

(6′) As shown in FIG. 7f, an interlayer medium layer 09 is deposited on the base substrate 01 where the carrier regulating layer 04 is formed, and a via hole 091 passing through the interlayer medium layer 09 is formed through a single patterning process.

(7′) As shown in FIG. 9, the patterns of the source electrode 07 and the drain electrode 08 electrically connected to the active layer 02 are formed on the base substrate 01 where the interlayer medium layer 09 is formed through the vie hole 091.

The bottom-gate array substrate shown in FIG. 9 provided in the present disclosure may be obtained through steps (1′) to (7′) in embodiment II.

It should be noted that during the above manufacturing process of the array substrate provided in the embodiments of the present disclosure, the pattering process may include a photoetching process, or may include a photoetching process and etching steps. Meanwhile, the pattering process may also include processes, such printing, ink-jetting and the like, for forming a specified pattern. The photoetching process refer to the process including the procedures of film formation, exposure, developing and the like for forming a pattern using photoresist, mask plates, exposure machines, etc. During implementation, the corresponding patterning process may be selected based on the structure to be formed in the present disclosure.

Based on the same invention concept, the embodiments of the present disclosure further provide a display apparatus, including the above array substrate provided in the embodiments of the present disclosure. The principle of solving problems by the display apparatus is similar to the one by the above-mentioned array substrate. Thus, the implementation of the display apparatus may be referred to the implementation of the above-mentioned array substrate, which is not repeated here.

The above display apparatus provided in the embodiments of the present disclosure may be an organic light-emitting display apparatus, and may also be a liquid crystal display apparatus, which is not limited here.

The above display apparatus provided in the embodiments of the present disclosure may be a full-screen display apparatus, and may also be a flexible display apparatus, etc, which is not limited here.

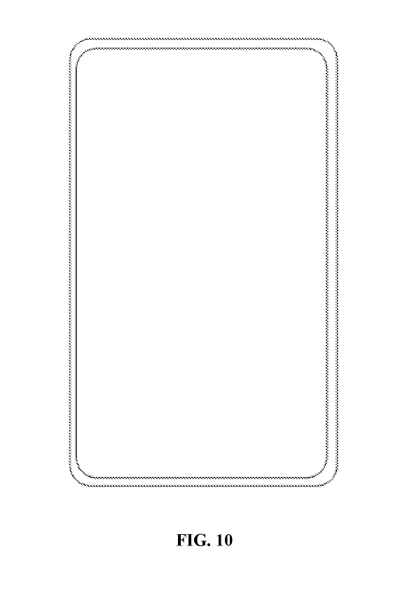

The above display apparatus provided in the embodiments of the present disclosure may be may be a full-screen mobile phone shown in FIG. 10. Certainly, the above display apparatus provided in the embodiments of the present disclosure may be may also be a tablet computer, a TV, a display, a laptop computer, a digital photo frame, a navigator and any other product or part with display function. Other essential components of the display apparatus are to be understood by persons of ordinary skill in the art, and therefore are not repeated here, which are also construed as limiting the present disclosure.

The embodiments of the present disclosure provide a thin film transistor, manufacturing method thereof and array substrate. The array substrate includes: a base substrate, and a thin film transistor on the base substrate. The thin film transistor includes an active layer, an insulating layer located at a side of the active layer, and a carrier regulating layer located at a side of the insulating layer facing away from the active layer. The orthographic projection of the active layer on the base substrate covers the orthographic projection of the carrier regulating layer on the base substrate. Wherein, the carrier regulating layer is configured to regulate carrier concentration in the active layer. In the present disclosure, by arranging the carrier regulating layer insulated from the active layer through the insulating layer, the carrier concentration in the carrier regulating layer may be regulated based on the need for different initial threshold voltages Vth of the TFT. During the manufacturing process of the thin film transistor, the Fermi energy reaches to a balanced state once the active layer, the insulating layer and the carrier regulating layer contact. During the process that the Fermi energy reaches to the balanced state, the active layer induces the same amount of charges opposite to the charges in the carrier regulating layer to realize the balanced state of the Fermi energy. That is, the amount of charges produced in the active layer is the same as the amount of charges carried in the carrier regulating layer. Thus, the carrier concentration in the active layer may be controlled and regulated simply by regulating the carrier concentration in the carrier regulating layer in advance, thereby regulating the value of the initial threshold voltage Vth of the TFT. Therefore, according to the array substrate provided in the embodiments of the present disclosure, there is no need to adjust the total oxygen content in the gate insulating layer and the active layer to control the threshold voltage Vth of the TFT, and different initial threshold voltages Vth of the TFT may be controlled and regulated simply by regulating the carrier concentration in the carrier regulating layer. In this way, the uniformity of the TFT film layers and the accurate control of the initial threshold voltage Vth of the TFT may be achieved simultaneously, thereby improving the electrical characteristics of the TFT.

Apparently, persons of ordinary skill in the art may make various modifications and variations to the present disclosure without departing from the spirits and scope thereof. The present disclosure is intended to include these modifications and variations if they fall within the scope of the claims of the present disclosure or the equivalent techniques thereof.

What is claimed is:

1. A thin film transistor, comprising: a carrier regulating layer, an insulating layer and an active layer, the insulating layer being located at a side of the active layer, the carrier regulating layer being located at a side of the insulating layer facing away from the active layer, an orthographic projection of the active layer on the insulating layer covering an orthographic projection of the carrier regulating layer on the insulating layer, wherein the carrier regulating layer is configured to regulate carrier concentration in the active layer.

2. The thin film transistor according to claim 1, wherein the carrier regulating layer is made of any one of P-type amorphous silicon and N-type amorphous silicon.

3. The thin film transistor according to claim 1, further comprising: a gate electrode, a gate insulating layer, and a source electrode and a drain electrode electrically connected to the active layer respectively, wherein the active layer is located between the insulating layer and the gate electrode, and the carrier regulating layer is located between a base substrate and the insulating layer.

4. The thin film transistor according to claim 3, wherein the orthographic projection of the active layer on the insulating layer completely overlaps the orthographic projection of the carrier regulating layer on the insulating layer.

5. The thin film transistor according to claim 1, further comprising: a gate electrode, a gate insulating layer, and a source electrode and a drain electrode electrically connected to the active layer respectively, wherein the gate electrode is located between a base substrate and the active layer, and the carrier regulating layer is located at a side of the insulating layer away from the base substrate.

6. The thin film transistor according to claim 1, wherein a thickness of the carrier regulating layer is 40-200 nm.

7. The thin film transistor according to claim 1, wherein a thickness of the active layer is 40-100 nm.

8. An array substrate, comprising: a base substrate, and thin film transistors on the base substrate, wherein the thin film transistors comprise an active layer, an insulating layer located at a side of the active layer, and a carrier regulating layer located at a side of the insulating layer facing away from the active layer, an orthographic projection of the active layer on the base substrate covering an orthographic projection of the carrier regulating layer on the base substrate; wherein the carrier regulating layer is configured to regulate carrier concentration in the active layer.

9. The array substrate according to claim 8, wherein the carrier regulating layer is made of any one of P-type amorphous silicon and N-type amorphous silicon.

10. The array substrate according to claim 8, wherein the thin film transistor further comprises: a gate electrode, a gate insulating layer, and a source electrode and a drain electrode electrically connected to the active layer, the active layer being located between the insulating layer and the gate electrode, and the carrier regulating layer being located between the base substrate and the insulating layer.

11. The array substrate according to claim 10, wherein the orthographic projection of the active layer on the insulating layer completely overlaps the orthographic projection of the carrier regulating layer on the insulating layer.

12. The array substrate according to claim 8, wherein the thin film transistor further comprises: a gate electrode, a gate insulating layer, and a source electrode and a drain electrode electrically connected to the active layer respectively, the gate electrode being located between the base substrate and the active layer, and the carrier regulating layer being located at a side of the insulating layer away from the base substrate.

13. The array substrate according to claim 8, wherein a thickness of the carrier regulating layer is 40-200 nm.

14. The thin film transistor according to claim 8, wherein a thickness of the active layer is 40-100 nm.

15. A manufacturing method for a thin film transistor, comprising steps of:
providing a base substrate; and
forming a carrier regulating layer, an insulating layer and an active layer on the base substrate, the insulating layer being located at a side of the active layer, the carrier regulating layer being located at a side of the insulating layer facing away from the active layer, an orthographic projection of the active layer on the insulating layer covering an orthographic projection of the carrier regulating layer on the insulating layer, wherein the carrier regulating layer is configured to regulate carrier concentration in the active layer.

16. The manufacturing method according to claim 15, wherein the carrier regulating layer in the thin film transistor is made in the following way:
adopting a single patterning process and a single doping process to form the carrier regulating layer; wherein the carrier regulating layer is doped with positive ions when threshold voltage of the thin film transistor is greater than a specified value, and the carrier regulating layer is doped with negative ions when the threshold voltage of the thin film transistor is less than the specified value.

17. The manufacturing method according to claim 15, wherein the thin film transistor further comprises: a gate electrode, a gate insulating layer, and a source electrode and a drain electrode electrically connected to the active layer respectively, the active layer being located between the insulating layer and the gate electrode, and the carrier regulating layer being located between the base substrate and the insulating layer, the manufacturing method comprising steps of:
forming a pattern of the carrier regulating layer on the base substrate by a single patterning process and a single doping process;
forming the insulating layer on the base substrate where the carrier regulating layer is formed;
forming a pattern of the active layer on the base substrate where the insulating layer is formed;
forming the gate insulating layer on the base substrate where the active layer is formed;
forming a pattern of the gate electrode on the base substrate where the gate insulating layer is formed; and
forming patterns of the source electrode and the drain electrode electrically connected to the active layer respectively on the base substrate where the gate electrode is formed.

18. The manufacturing method according to claim 15, wherein the thin film transistor further comprises: a gate electrode, a gate insulating layer, and a source electrode and a drain electrode electrically connected to the active layer respectively, the gate electrode being located between the base substrate and the active layer, and the carrier regulating layer being located at a side of the insulating layer away from the base substrate, the manufacturing method comprising steps of:
forming a pattern of the gate electrode on the base substrate;
forming the gate insulating layer on the base substrate where the gate electrode is formed;
forming a pattern of the active layer on the base substrate where the gate insulating layer is formed;
forming the insulating layer on the base substrate where the active layer is formed;
forming a pattern of the carrier regulating layer on the base substrate where the insulating layer is formed by a single patterning process and a single doping process; and
forming patterns of the source electrode and the drain electrode electrically connected to the active layer respectively on the base substrate where the carrier regulating layer is formed.

19. The manufacturing method according to claim 16, wherein the step of adopting a single patterning process and a single doping process to form the carrier regulating layer comprises:
forming the carrier regulating layer made of one of P-type amorphous silicon and N-type amorphous silicon by a single patterning process and a single doping process.

20. A display device comprising the array substrate according to claim 8.
